(19) United States
(12) Patent Application Publication
(10) Pub. No.: US 2025/0153134 A1
(43) Pub. Date: May 15, 2025

(54) SURFACE TREATMENT APPARATUS

(71) Applicant: Shibaura Machine Co., Ltd., Tokyo (JP)

(72) Inventors: Takeshi NAMBA, Numazu-shi (JP); Kazuhiro FUKADA, Sunto-gun (JP); Yoshiaki KURIHARA, Sunto-gun (JP)

(73) Assignee: Shibaura Machine Co., Ltd., Tokyo (JP)

(21) Appl. No.: 18/838,444

(22) PCT Filed: Jan. 16, 2023
(86) PCT No.: PCT/JP2023/000971

§ 371 Date: Aug. 14, 2024

(30) Foreign Application Priority Data
Feb. 22, 2022 (JP) 2022-025886

(51) Int. Cl. B01J 19/08; B01J 19/18; C23C 14/22; C23C 14/34

(52) U.S. Cl. CPC B01J 19/087; B01J 19/18; C23C 14/223; C23C 14/34; B01J 2219/0894

(57) ABSTRACT

A surface treatment apparatus includes a treatment electrode, a housing unit that is installed at a position facing the treatment electrode and is rotatable around a rotation shaft having an inclination with respect to a horizontal direction while housing a workpiece, a chamber that houses the treatment electrode and the housing unit, a surface treatment device that performs surface treatment on the workpiece housed in the housing unit and includes the treatment electrode, and a rotation device that rotates the housing unit around the rotation shaft when the surface treatment device performs the surface treatment on the workpiece.

### TECHNICAL FIELD

The present invention relates to a surface treatment apparatus that performs a surface treatment such as irradiation of a workpiece with plasma.

### BACKGROUND ART

There are known surface treatment apparatuses of forming a metal catalyst layer, a functional group, or the like by cleaning or reforming a surface of a workpiece using plasma, and surface treatment apparatuses of performing sputtering using a sputtering apparatus.

For example, in a plasma deposition apparatus described in Patent Document 1, a plurality of substrate holders used as anode electrodes are installed, and a plurality of cathode electrodes is formed between the plurality of substrate holders. In this apparatus, by introducing a process gas between the electrodes and supplying AC power between the electrodes, the process gas is brought into a plasma state to generate a thin film on the substrate. Patent Document 2 is an application filed by the same applicant as the present application for solving the same issues.

### CITATION LIST

### Patent Literature

Patent Document 1: JP 5768890 B
Patent Document 2: WO 2021/060160 A

### SUMMARY OF INVENTION

### Problems to be Solved by the Invention

The plasma deposition apparatus of Patent Document 1 is suitable for depositing a large amount of thin plate-shaped components. However, this apparatus cannot uniformly irradiate the surface of a small component in a three-dimensional shape with plasma, having a difficulty in uniformly depositing a film on the entire surface of the small component in a three-dimensional shape.

The present invention has been made in view of the above, and aims to provide a surface treatment apparatus capable of uniformly performing surface treatment on the entire surface of a workpiece even when the workpiece to be subjected to the surface treatment has a small three-dimensional shape.

### Means for Solving Problem

In order to solve the above problem and achieve the object, a surface treatment apparatus according to the present invention includes: a treatment electrode; a housing unit that is installed at a position facing the treatment electrode and is rotatable around a rotation shaft having an inclination with respect to a horizontal direction while housing a workpiece; a chamber that houses the treatment electrode and the housing unit; a surface treatment device that performs surface treatment on the workpiece housed in the housing unit, and includes the treatment electrode; and a rotation device that rotates the housing unit around the rotation shaft when the surface treatment device performs the surface treatment on the workpiece.

### Effect of the Invention

The surface treatment apparatus according to the present invention has an effect of capable of performing surface treatment uniformly on the entire surface of a workpiece to be subjected to surface treatment even when the workpiece is a small component with a three-dimensional shape.

### BRIEF DESCRIPTION OF DRAWINGS

FIG. 1 is a schematic view illustrating a schematic configuration of a surface treatment apparatus according to a first embodiment;

FIG. 2A is a side view illustrating an example of a schematic configuration of a barrel;

FIG. 2B is a cross-sectional view taken along line A-A of FIG. 2A;

FIG. 3A is a view illustrating an example of a structure of a side wall of the barrel in FIG. 2A;

FIG. 3B is a view illustrating an example of another structure of the side wall of the barrel in FIG. 2A;

FIG. 4A is a side view illustrating another example of the schematic configuration of the barrel;

FIG. 4B is a cross-sectional view taken along line D-D in FIG. 4A;

FIG. 5A is a view illustrating an example of a structure of a side wall of the barrel in FIG. 4A;

FIG. 5B is a cross-sectional view taken along line E-E of FIG. 5A;

FIG. 6 is a schematic view in a case where a plasma treatment apparatus is located in a chamber;

FIG. 7 is a schematic diagram when a sputtering apparatus is located in a chamber;

FIG. 8 is a diagram illustrating a configuration of a plasma treatment apparatus;

FIG. 9 is a diagram illustrating a configuration of a sputtering apparatus;

FIG. 10 is a schematic view illustrating a schematic configuration of a surface treatment apparatus according to a modification of the first embodiment;

FIG. 11 is an external perspective view illustrating an example of a schematic configuration of a barrel used in a surface treatment apparatus according to a second embodiment; and

FIG. 12 is side view illustrating an example of a schematic configuration of a barrel used in a surface treatment apparatus according to the second embodiment.

### DESCRIPTION OF EMBODIMENTS

Hereinafter, an embodiment of a surface treatment apparatus according to the present disclosure will be described in detail with reference to the drawings. Note that the present invention is not limited by the embodiment. In addition, constituent elements in the following embodiments include those that can be replaced by those skilled in the art and can be easily conceived, or those that are substantially the same.

### First Embodiment

An embodiment of the present disclosure is presented as an example of a surface treatment apparatus 1 that generates a functional group on a surface of a workpiece W including a resin material, for example, by irradiating the surface of the workpiece W with plasma, and thereafter forms a thin film by sputtering on the surface of the workpiece W having improved adhesion of the film due to the generation of the functional group.

### (Schematic Configuration of Surface Treatment Apparatus)

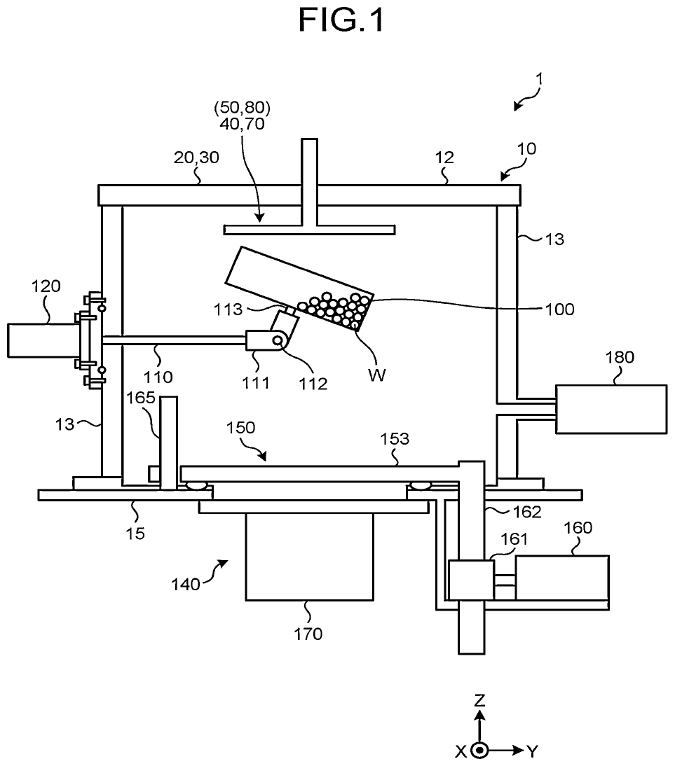

A schematic configuration of the surface treatment apparatus 1 will be described with reference to FIG. 1. FIG. 1 is a schematic view illustrating a schematic configuration of a surface treatment apparatus according to a first embodiment;

The surface treatment apparatus 1 according to the first embodiment includes: a chamber 10 capable of housing the workpiece W inside thereof; a plasma treatment apparatus 40 as an example of a surface treatment device that performs surface treatment on the workpiece W; a sputtering apparatus 70 as an example of a surface treatment device that performs surface treatment different from the plasma treatment apparatus 40, on the workpiece W; a barrel 100 that houses the workpiece W; and a pump unit 140 that decompresses the inside of the chamber 10 and exhausts gas in the chamber 10. The workpiece W has a small three-dimensional shape including a resin material such as plastic resin.

For facilitate description, a coordinate system XYZ is set. The X axis is an axis passing through FIG. 1 in a direction orthogonal to the page surface. The Y axis is an axis passing through FIG. 1 in the left-right direction. The Z axis is an axis orthogonal to both the X axis and the Y axis.

The plasma treatment apparatus 40 generates plasma and irradiates the workpiece W with the generated plasma to perform surface treatment on the workpiece W. More specifically, by irradiating the surface of the workpiece W with plasma, the apparatus generates a functional group, for example. This increases the adhesion of the thin film at a time of generating a thin film to be a base for plating on the surface of the workpiece W in the subsequent step.

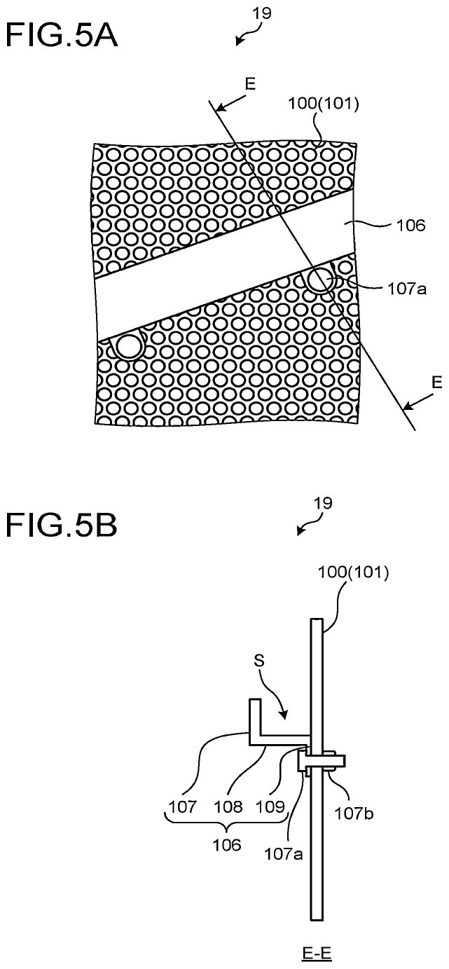

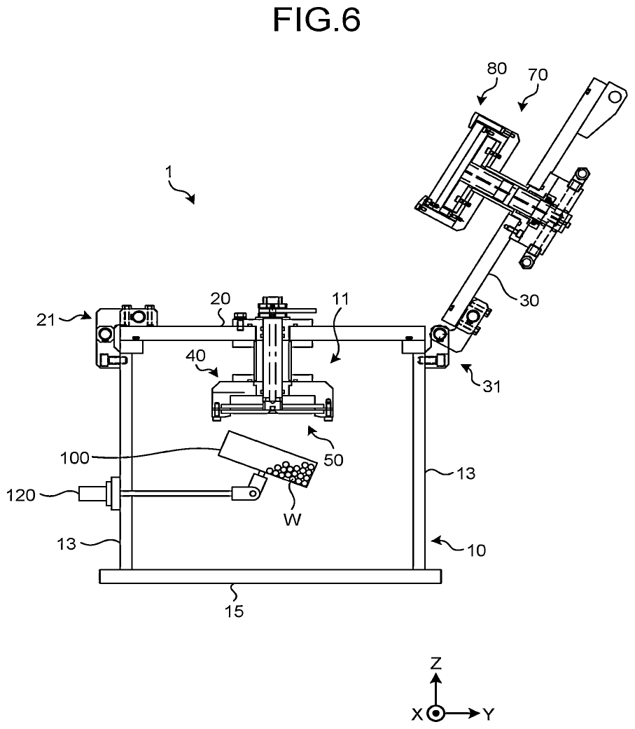

The sputtering apparatus 70 performs sputtering on the workpiece W that has undergone surface treatment by the plasma treatment apparatus 40, thereby performing surface treatment of forming a thin film to be a base of plating on the workpiece W. As will be described below, the plasma treatment apparatus 40 and the sputtering apparatus 70 can continuously perform different surface treatments on the same workpiece W by switching apparatuses disposed in the chamber 10 (refer to FIGS. 6 and 7).

Note that FIG. 1 illustrates a positional relationship of the plasma treatment apparatus 40 and the sputtering apparatus 70 in the chamber 10 when located in the chamber 10, and thus is a schematic view applicable in either case where the apparatus located in the chamber 10 is the plasma treatment apparatus 40 or the sputtering apparatus 70. The chamber 10 is formed in a hollow substantially rectangular parallelepiped shape. The plasma treatment apparatus 40 and the sputtering apparatus 70 are disposed in the chamber 10 so as to be attached to an upper wall 12 which is a wall surface on the upper side of the chamber 10. More specifically, the chamber 10 includes a plasma electrode 50 that generates plasma by the plasma treatment apparatus 40 or includes a sputtering electrode 80 on which a target of ejecting atoms used for deposition is attached in the sputtering apparatus 70. The plasma electrode 50 and the sputtering electrode 80 are examples of treatment electrodes in the present disclosure.

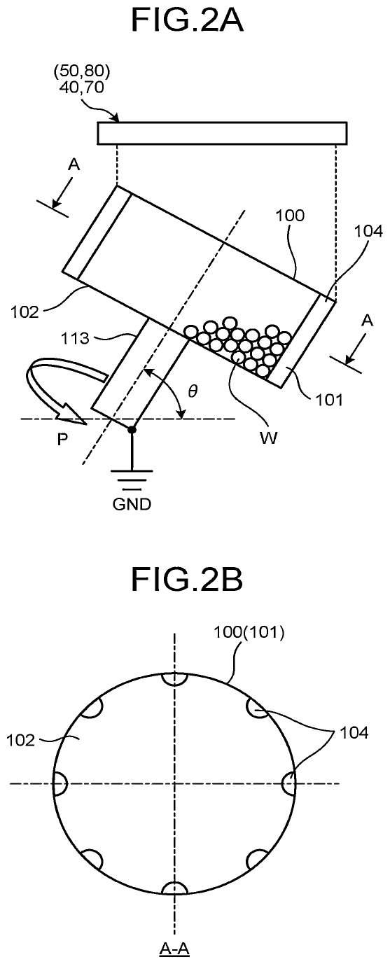

The barrel 100 is installed in the chamber 10 while being supported by a rotation shaft 110, a universal joint 111, and a rotation shaft 113. The chamber 10 can house the workpiece W inside thereof. The detailed structure of the barrel 100 will be described below (refer to FIGS. 2A to 5B). The barrel 100 is an example of a housing unit in the present disclosure.

The rotation shaft 110 is disposed along the Y axis, and rotates in an optionally preset rotation pattern, that is, at an optionally determined rotation speed, by a servo motor 120 installed on a side wall 13 of the chamber 10 when the plasma treatment apparatus 40 or the sputtering apparatus 70 performs surface treatment on the workpiece W. The servo motor 120 is an example of a rotation device in the present disclosure.

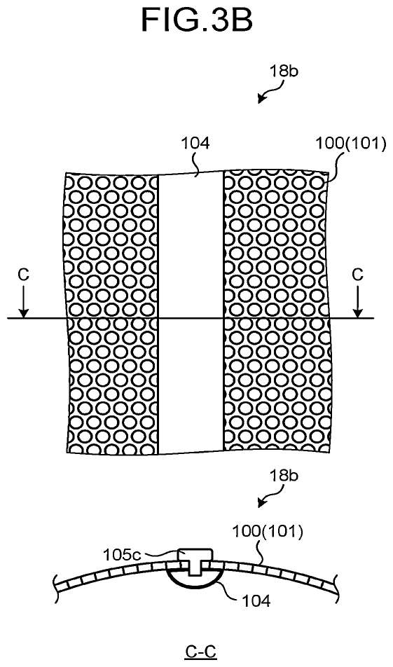

The rotational force of the rotation shaft 110 is converted into the rotational force of the rotation shaft 113 at a rotation shaft fulcrum 112 of the universal joint 111. The barrel 100 is rotated by the rotational force of the rotation shaft 113. The rotation shaft 113 is disposed with an inclination (refer to FIGS. 2A and 4A) of an angle θ with respect to the horizontal direction (Y-axis direction). The angle θ is fixed during the rotation of the barrel 100.

Since the workpiece W housed in the barrel 100 is stirred with the rotation of the barrel 100, enabling the plasma treatment apparatus 40 and the sputtering apparatus 70 to perform uniform surface treatment on the surface of the workpiece W. In particular, with a structure to be described below (refer to FIGS. 2A to 5B), the barrel 100 of the first embodiment has an improved stirring efficiency.

As illustrated in FIG. 1, the pump unit 140, attached to the bottom portion 15 of the chamber 10, sucks the fluid in the chamber 10, that is, the gas in the chamber 10 to reduce the pressure in the chamber 10.

The pump unit 140 includes: a flow rate regulating valve 150 being a valve unit of regulating the flow rate of the fluid, and a turbomolecular pump 170 being a pump of sucking a fluid. The pump unit 140 regulates the flow rate of the fluid sucked by the turbomolecular pump 170 with the flow rate regulating valve 150 to reduce the pressure in the chamber 10 to a desired pressure. In addition, the pump unit 140 sucks the gas that enters from the upper portion of the barrel 100 from immediately below the barrel 100. The pump unit 140 is an example of an exhaust device in the present disclosure.

The flow rate regulating valve 150 includes: an elevating valve 153 disposed in the chamber 10; and a servo actuator 160 being a driving device of vertically moving the elevating valve 153 along the Z axis in the chamber 10. The elevating valve 153 moves along the Z axis in the chamber 10 to regulate the flow rate of the fluid to be sucked by the turbomolecular pump 170. The elevating valve 153 had its open/close operation guided by a valve guide 165.

The flow rate regulating valve 150 further includes: an elevating shaft 162 to which the elevating valve 153 is connected; and a worm jack 161 that transmits power generated by the servo actuator 160 to the elevating shaft 162 to move the elevating shaft 162 along the Z axis. There is provided a vacuum gauge 180 attached to the chamber 10, and the pressure in the chamber 10 is detected by the vacuum gauge 180. The servo actuator 160 operates based on a detection value, being a value detected by the vacuum gauge 180, thereby moving the elevating valve 153 along the Z axis based on the detection value detected by the vacuum gauge 180 so as to regulate the flow rate of the fluid to be sucked by the turbomolecular pump 170.

### (Example of Barrel Structure)

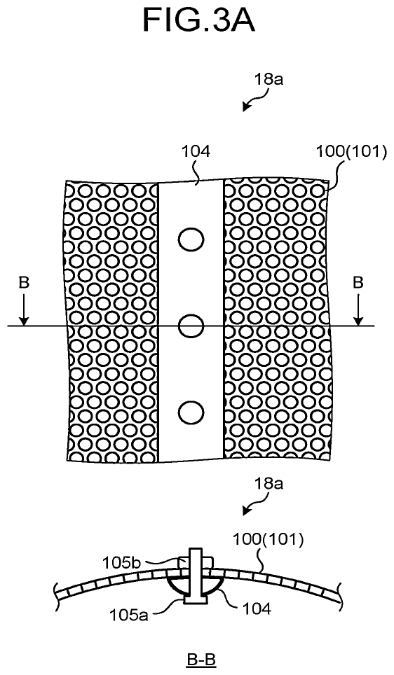

The structure of the barrel 100 will be described with reference to FIGS. 2A, 2B, 3A, and 3B. FIG. 2A is a side view illustrating an example of a schematic configuration of a barrel. FIG. 2B is a cross-sectional view taken along line A-A of FIG. 2A. FIG. 3A is a view illustrating an example of a structure of a side wall of the barrel in FIG. 2A. FIG. 3B is a view illustrating an example of another structure of the side wall of the barrel in FIG. 2A.

The barrel 100 has a side wall 101 and a bottom surface 102 formed with a material having a plurality of small holes on the surface (refer to FIGS. 3A and 3B), such as perforated metal. In addition, the upper surface of the barrel 100 is open. The rotation shaft 113 of the barrel 100 is inclined at an angle θ with respect to the horizontal direction. That is, the bottom surface 102 of the barrel 100 is inclined with respect to the orientation of the plasma electrode 50 of the plasma treatment apparatus 40 or the sputtering electrode 80 of the sputtering apparatus 70. The angle θ can be changed by the universal joint 111 (refer to FIG. 1), and is set to a range of approximately 45° to 80°. Inside the barrel 100, a plurality of workpieces W are housed. The size of the workpiece W is larger than the hole of the perforated metal forming the side wall 101. The workpiece W is stirred by the rotation of the barrel 100 around the rotation shaft 113, that is, in the direction of arrow P. A plasma gas generated in the plasma electrode 50 of the plasma treatment apparatus 40 installed above the barrel 100 or an atom ejected from a target attached to the sputtering electrode 80 of the sputtering apparatus 70 enters the barrel 100 from above the barrel 100 and reacts with the workpiece W. The plasma gas and the atoms ejected from the target react with the workpiece W and then are exhausted from the bottom surface 102. With this configuration, uniform surface treatment is performed on the surface of the workpiece W subjected to stir.

An opening end of the barrel 100 has dimensions within the range of the plasma electrode 50 or the sputtering electrode 80. Specifically, when the opening end of the barrel 100 is projected in the direction of the plasma electrode 50 or the sputtering electrode 80, the opening portion of the barrel 100 falls within the range of the plasma electrode 50 or the sputtering electrode 80 as indicated by the dotted line in FIG. 2A.

As illustrated in the cross-sectional view taken along line A-A of FIG. 2B, a plurality of protrusions 104 having a semi-cylindrical shape is formed on the side wall 101 of the barrel 100. In the example of FIG. 2B, the protrusion 104 is formed at eight positions at 45° intervals. When the barrel 100 rotates around the rotation shaft 113, the stirred workpiece W collides with the protrusion 104 and bounces back, allowing the workpiece W to be further stirred.

FIGS. 3A and 3B are views illustrating a method of fixing the protrusion 104 to the side wall 101 of the barrel 100. The protrusion 104 is fixed, with a bolt, to the hole of a perforated metal forming the side wall 101 of the barrel 100.

An attachment structure 18a illustrated in FIG. 3A is a view of the side wall 101 of the barrel 100 as viewed from the inside of the barrel 100. The B-B cross-sectional view is a cross-sectional view of the side wall 101 of the barrel 100 having the attachment structure 18a of the protrusion 104 taken along a cutting line crossing the protrusion 104.

The attachment structure 18a is an example in which a bolt 105a is passed through a hole of the perforated metal forming the protrusion 104 and the side wall 101 from the protrusion 104, and then a nut 105b is fastened to a tip of the bolt 105a after penetration, thereby fixing the protrusion 104 to the side wall 101. The bolt 105a may be inserted from the hole of the perforated metal forming the side wall 101, that is, from the outside of the barrel 100.

An attachment structure 18b illustrated in FIG. 3B is a view of the side wall 101 of the barrel 100 as viewed from the inside of the barrel 100. The C-C cross-sectional view is a cross-sectional view of the side wall 101 of the barrel 100 having the attachment structure 18b of the protrusion 104 taken along a cutting line crossing the protrusion 104.

The attachment structure 18b is an example in which a tip of a bolt 105c inserted from the outside of the barrel 100 through a hole on the perforated metal forming the side wall 101 is fastened to a screw hole formed in the protrusion 104, thereby fixing the protrusion 104 to the side wall 101.

In attachment structures 18a and 18b, the protrusion 104 is fastened at a plurality of positions in the extending direction of protrusions 104 using the bolt 105a and the nut 105b, or using the bolt 105c, respectively. In addition, using a structure to be fixed to the side wall 101 with the bolt 105a (or 105c), the protrusion 104 is to be easily attached/detached. This makes it possible to change the size, shape, and number of the protrusions 104 according to the shape, size, and the like of the workpiece W housed in the barrel 100.

### (Another Example of Barrel Structure)

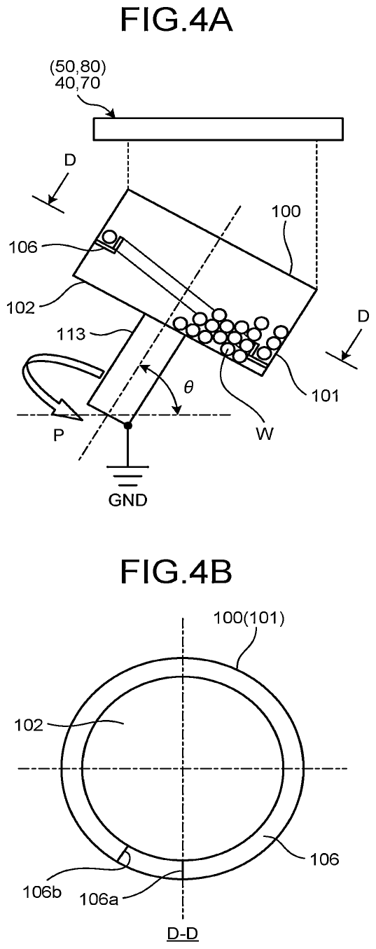

Another structure of the barrel 100 will be described with reference to FIGS. 4A, 4B, 5A, and 5B. FIG. 4A is a side view illustrating another example of the schematic configuration of the barrel. FIG. 4B is a cross-sectional view taken along line D-D in FIG. 4A. FIG. 5A is a view illustrating an example of a structure of a side wall of the barrel in FIG. 4A. FIG. 5B is a cross-sectional view taken along line E-E of FIG. 5A.

As illustrated in FIG. 4A, there is provided a screw 106 on the inside the side wall 101 of the barrel 100 along the side wall 101. The screw 106 forms a groove S having a spiral shape (refer to FIG. 5B). As illustrated in the cross-sectional view taken along line D-D in FIG. 4B, the screw 106 has one end 106a and the other end 106b.

When the barrel 100 rotates around the rotation shaft 113, a part of the workpiece W gets into the groove S of the screw 106 from the end 106a on the bottom surface 102 side in the vicinity of the bottom surface 102 of the barrel 100. The workpiece W having entered the groove S moves along the groove S of the screw 106. The workpiece W is then discharged into the barrel 100 from the end 106b of the screw 106 on the side away from the bottom surface 102. In this manner, the screw 106 promotes stirring of the workpiece W housed in the barrel 100.

Although FIG. 4A illustrates an example in which one screw 106 is provided, it is allowable to provide a plurality of screws 106 on the inside of the side wall 101. The positions of the ends 106a and 106b of the screw 106 may be flexibly set. Furthermore, when a plurality of screws 106 is provided, the positions of the ends 106a and 106b of the screws 106 may be shifted.

FIG. 5A is a view illustrating a method of fixing the screw 106 to the side wall 101 of the barrel 100. The screw 106 is fixed, using a bolt 107a, to a hole of the perforated metal forming the side wall 101 of the barrel 100.

An attachment structure 19 illustrated in FIG. 5A is a view of the side wall 101 of the barrel 100 as viewed from the inside of the barrel 100. In addition, the E-E cross-sectional view illustrated in FIG. 5B is a cross-sectional view of the side wall 101 of the barrel 100 having the attachment structure 19 for the screw 106, taken along a cutting line crossing the screw 106.

The attachment structure 19 is an example in which the bolt 107a is passed through the screw 106 and a hole of the perforated metal forming the side wall 101 of the barrel 100 from the screw 106 side, and then the bolt 107a is fastened with a nut 107b, whereby the screw 106 is fixed to the side wall 101. The bolt 107a may be inserted from the hole of the perforated metal forming the side wall 101, that is, from the outside of the barrel 100.

As illustrated in the cross-sectional view taken along line E-E, the screw 106 includes a side wall 107, a bottom surface 108, and an attachment portion 109. The side wall 107 and the bottom surface 108 located at an angle of approximately 90° and form a groove S together with the side wall 101 of the barrel 100. The bolt 107a is inserted through a bolt hole formed in the attachment portion 109 and through a hole on the perforated metal forming the side wall 101 and is fastened to a nut 107c, whereby the screw 106 is fixed to the side wall 101 of the barrel 100.

### (Structure of Switching Different Types of Surface Treatment Device)

With reference to FIGS. 6 and 7, the following describes a structure in which the surface treatment apparatus 1 switches between the plasma treatment apparatus 40 and the sputtering apparatus 70, which are different types of surface treatment device. FIG. 6 is a schematic view in a case where a plasma treatment apparatus is located in a chamber. FIG. 7 is a schematic diagram when a sputtering apparatus is located in a chamber.

The chamber 10 has an opening 11 at the top. Either the plasma treatment apparatus 40 or the sputtering apparatus 70 is brought into the chamber 10 through the opening 11 so as to be selectively installed in the chamber 10. Specifically, as illustrated in FIG. 6, the plasma treatment apparatus 40 is disposed on a first open/close member 20 that is openably/closably attached to the chamber 10 at a hinge 21. On the other hand, the sputtering apparatus 70 is disposed on a second open/close member 30 that is openably/closably attached to the chamber 10 at a hinge 31.

Both the first open/close member 20 and the second open/close member 30 have a substantially rectangular shape in plan view, and have a shape substantially equal to the shape of the outer periphery formed by the plurality of side walls 13 when the chamber 10 is projected in a vertical direction Z. Accordingly, the first open/close member 20 and the second open/close member 30 have shapes capable of covering the opening 11 of the chamber 10. That is, the first open/close member 20 and the second open/close member 30 cover the opening 11 of the chamber 10 to close the opening 11. The first open/close member 20 and the second open/close member 30 are pivotably attached to the chamber 10. With this structure, the first open/close member 20 and the second open/close member 30 pivot with respect to the chamber 10 to open and close the opening 11.

The first open/close member 20 has its one side of the rectangular shape connected to one of the side walls 13 of the chamber 10 via the hinge 21. The hinge 21 pivotably connects the first open/close member 20 to the chamber 10 with a pivot shaft extending in the horizontal direction as a supporting shaft. The first open/close member 20 pivots about the hinge 21 to switch between positions, that is, a position in a state where the opening 11 of the chamber 10 is covered and the opening 11 is closed and a position in a state where the opening 11 is flipped up and the opening 11 is open. The plasma treatment apparatus 40 is attached to penetrate the first open/close member 20 in the thickness direction of the first open/close member 20. In addition, the plasma treatment apparatus 40 is attached to the first open/close member 20 in a direction to allow a portion (plasma electrode 50) generating plasma in the plasma treatment apparatus 40 to be orientated to be located within the chamber 10 when the first open/close member 20 pivotably connected to the chamber 10 is closed.

The second open/close member 30 has its one side of the rectangular shape connected to the side wall 13 facing the side wall 13 to which the first open/close member 20 is connected, among the plurality of side walls 13 of the chamber 10, via the hinge 31. The hinge 31 pivotably connects the second open/close member 30 to the chamber 10 with a pivot shaft extending in the horizontal direction as a supporting shaft. The second open/close member 30 pivots about the hinge 31 to switch between positions, that is, a position in a state where the opening 11 of the chamber 10 is covered and the opening 11 is closed and a position in a state where the opening 11 is flipped up and the opening 11 is open. The sputtering apparatus 70 is attached to penetrate the second open/close member 30 in the thickness direction of the second open/close member 30. In addition, the sputtering apparatus 70 is attached to the second open/close member 30 in a direction to allow a portion (sputtering electrode 80) that performs sputtering in the sputtering apparatus 70 to be orientated to be located within the chamber 10 when the second open/close member 30 pivotably connected to the chamber 10 is closed.

Regarding the states of the first open/close member 20 and the second open/close member 30 when the opening 11 of the chamber 10 is closed, either one of the first open/close member 20 or the second open/close member 30 is closed and the other is open. That is, either one of the first open/close member 20 or the second open/close member 30 closes the opening 11 of the chamber 10 in a state where the opening 11 is not closed by the other one of the members. Accordingly, the first open/close member 20 closes the opening 11 in a state where the opening 11 is not closed by the second open/close member 30, thereby positioning the plasma electrode 50 of the plasma treatment apparatus 40 to the inside of the chamber 10 (refer to FIG. 6). Similarly, the second open/close member 30 closes the opening 11 in a state where the opening 11 is not closed by the first open/close member 20, thereby positioning the sputtering electrode 80 of the sputtering apparatus 70 to the inside of the chamber 10 (refer to FIG. 7).

### (Structure of Plasma Treatment Apparatus)

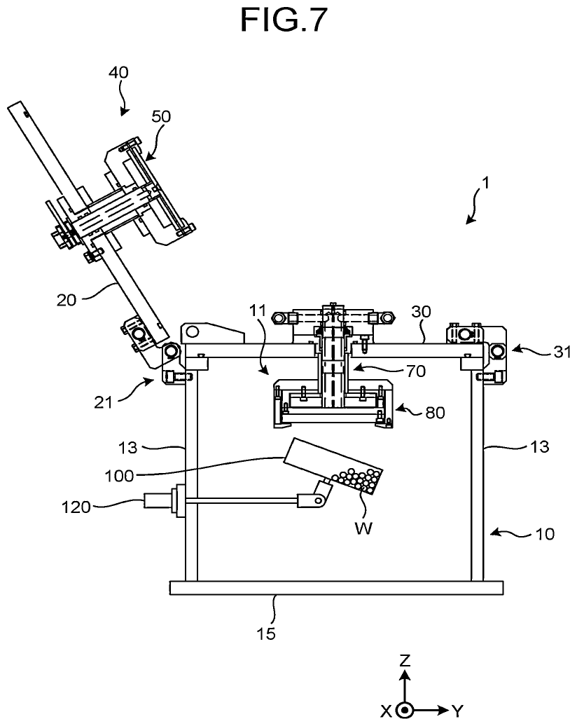

A configuration of the plasma treatment apparatus 40 will be described with reference to FIG. 8. FIG. 8 is a cross-sectional view illustrating an example of a configuration of a plasma treatment apparatus.

The plasma treatment apparatus 40 includes: a gas supply pipe 66 that supplies a reaction gas such as argon used in generating a plasma gas; and a pair of plate-shaped conductors 60 and 62 that generates, using a radio frequency voltage, a plasma gas from the reaction gas supplied from the gas supply pipe 66. Examples of the reaction gas to be used include oxygen, argon, nitrogen, alone or in a mixed state of these gases.

The gas supply pipe 66 penetrates a support plate 77, which is supported on a side wall surface of the chamber 10 so as to be movable along the Z axis (Z1 axis), in the thickness direction, and is attached to a support plate 77 by a gas supply pipe attachment member 58. Inside the gas supply pipe 66, a gas flow path 56 along the extending direction of the gas supply pipe 66 is formed, and the reaction gas is supplied from the outside of the chamber 10 into the chamber 10 through the gas flow path 56. The gas supply pipe 66 has its end on the outer side of the support plate 77 (the outer side of the chamber 10) connected to a gas supply portion 78 that supplies the reaction gas to the gas supply pipe 66, while the gas supply pipe 66 has its other end (the inner side of the chamber 10) connected to a gas supply hole 57 being a hole introducing the reaction gas flowing through the gas flow path 56 into the chamber 10. The reaction gas is supplied to the gas supply portion 78 through a mass flow controller (MFC) 76 being a mass flowmeter having a flow rate control function.

The pair of plate-shaped conductors 60 and 62 is each formed in a flat plate shape, using metal plates such as aluminum or other conductor plates arranged in parallel. The plate-shaped conductors 60 and 62 form the plasma electrode 50. The support plate 77 includes a conductive material such as an aluminum alloy, for example. The support plate 77 is formed in a plate-like shape in which a recess 67 recessed along the outer periphery is formed on the negative side on the Z-axis, that is, on the inner side of the chamber 10.

The support plate 77 is supported by a support member 59. The support member 59 includes a cylindrical member and attachment members located at both ends of the cylindrical member, and an end of the support member 59 on the negative side on the Z-axis is attached to the support plate 77.

The gas supply pipe 66 penetrating the support plate 77 passes through the inside of the cylindrical support member 59 to extends to the position of the support plate 77, and penetrates the support plate 77. The gas supply hole 57 formed in the gas supply pipe 66 is disposed in a portion of the support plate 77 where the recess 67 is formed.

The pair of plate-shaped conductors 60 and 62 is disposed on the support plate 77 on the side of the recess 67 so as to cover the recess 67. Between the pair of plate-shaped conductors 60 and 62, a spacer 63 is provided in the vicinity of the outer periphery, and they are lapped over each other via the spacer 63. The pair of plate-shaped conductors 60 and 62 is disposed apart from each other in a portion other than the spacer 63 to form a void 61 between the plate-shaped conductors 60 and 62. The interval, namely, the size of the void 61 is preferably appropriately set according to the frequency of the reaction gas introduced in the plasma treatment apparatus 40 or the power to be supplied, the size of the electrode, and the like, and is set to a range of approximately 2 mm to 12 mm.

The pair of plate-shaped conductors 60 and 62 is retained by a retaining member 79 which is a member for retaining the plate-shaped conductors 60 and 62, while being lapped over each other via the spacer 63. That is, the retaining member 79 is disposed on the opposite side of the side where the support plate 77 is located in the plate-shaped conductors 60 and 62, and is attached to the support plate 77 in a state where the plate-shaped conductors 60 and 62 are sandwiched between the retaining member 79 and the support plate 77. In addition, there is a space formed between the recess 67 of the support plate 77 and the plate-shaped conductors 60 and 62.

The space formed in this manner functions as a gas introduction portion 64 into which the reaction gas supplied by the gas supply pipe 66 is introduced. The gas supply hole 57 of the gas supply pipe 66 is located in the gas introduction portion 64 and is open toward the gas introduction portion 64.

The pair of plate-shaped conductors 60 and 62 respectively has a large number of through holes 68 and 69 penetrating in the thickness direction. Specifically, a plurality of through holes 69 is formed at predetermined intervals in a matrix in the plate-shaped conductor 62 located on an inflow side of the reaction gas supplied by the gas supply pipe 66, while a plurality of through holes 68 is formed at predetermined intervals in a matrix in the plate-shaped conductor 60 located on an outflow side of the reaction gas supplied by the gas supply pipe 66.

The through holes 68 of the plate-shaped conductor 60 and the through holes 69 of the plate-shaped conductor 62 are cylindrical holes, and both the through holes 68 and 69 are coaxially arranged. That is, the through hole 68 of the plate-shaped conductor 60 and the through hole 69 of the plate-shaped conductor 62 are arranged at positions where the centers of the through holes are aligned. In this manner, the pair of plate-shaped conductors 60 and 62 are to be electrodes respectively having the plurality of through holes 68 and 69, and the generated plasma gas flows through the plurality of through holes 68 and 69.

The void 61 is located between the parallel plate-shaped conductors 60 and 62, and the void 61 functions as a capacitor having electrostatic capacitance. The support plate 77 and the plate-shaped conductors 60 and 62 is provided with a conductive portion (not illustrated) including a conductive member. The support plate 77 is grounded to the earth 75 and the plate-shaped conductor 62 is also grounded to the earth 75 by the conductive portion. In addition, one end of the radio frequency power source (RF) 74 is grounded to the earth 75, while the other end of the radio frequency power source 74 is electrically connected to the plate-shaped conductor 60 via a matching box (MB) 73 for adjusting capacitance and the like to obtain matching with plasma. Therefore, when the radio frequency power source 74 is operated, the potential of the plate-shaped conductor 60 indicates positive and negative values at a predetermined frequency such as 13.56 MHZ.

The generated plasma gas flows out from the through hole 68. The plasma gas that has flowed out reacts with a deposition gas ejected from a gas supply pipe (not illustrated) on the negative side of the through hole 69 on the Z-axis. The reaction between the plasma gas and the deposition gas generates a precursor, and the generated precursor is used to perform surface treatment such as deposition and cleaning on the workpiece W.

The plasma treatment is performed by disposing the barrel 100 housing the workpiece W inside thereof, outside the plate-shaped conductors 60 and 62 being a pair of electrodes. This makes it possible to switch different types of surface treatment device as illustrated in FIGS. 6 and 7, enabling continuous operations of different surface treatments while keeping the workpiece W housed in the barrel 100. This configuration also increases the degree of freedom for changing the structure and angle θ of the barrel 100.

When the plasma treatment apparatus 40 is operating, the barrel 100 illustrated in FIG. 6 rotates, and thus, the workpiece W housed in the barrel 100 is stirred to perform uniform surface treatment on the workpiece W.

### (Structure of Sputtering Apparatus)

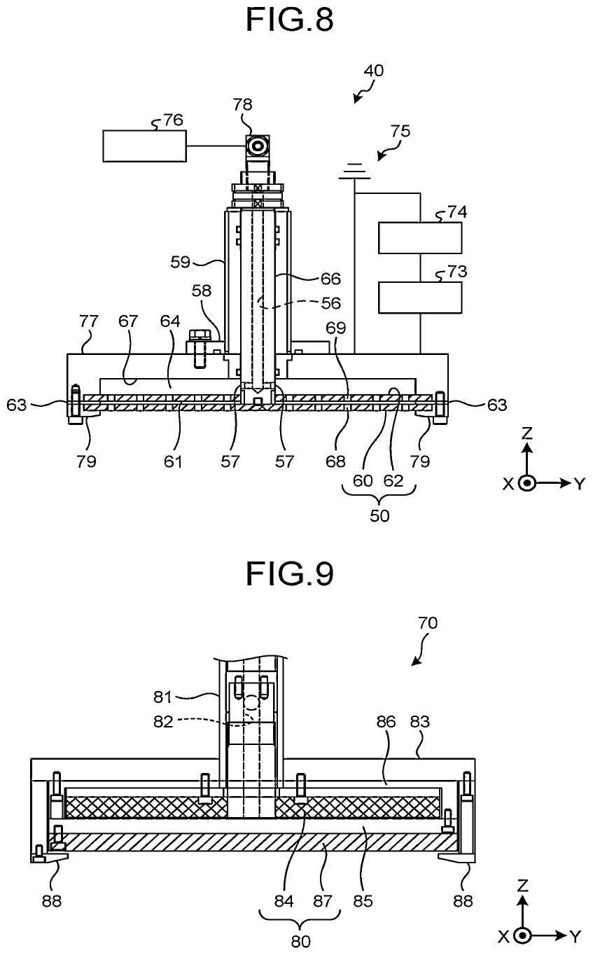

A configuration of the sputtering apparatus 22 will be described with reference to FIG. 9. FIG. 9 is a cross-sectional view illustrating an example of a configuration of the sputtering apparatus.

The sputtering apparatus 70 includes a cooling water pipe 81, a magnet 84, a target 87, a cooling jacket 85, and a support plate 83.

The cooling water pipe 81 forms a flow path of cooling water to be supplied to the cooling jacket 85. The magnet 84 generates a magnetic field.

The target 87 ionizes a sputtering inert gas ejected from a gas supply pipe (not illustrated) so as to let the gas collide with the target 87 inside a magnetic field generated by the magnet 84, thereby ejecting atoms used for deposition. The target 87 is, for example, a copper plate or an aluminum plate. Copper atoms or aluminum atoms ejected from the target 87 adhere to the surface of the workpiece W to form a thin film of copper or aluminum on the surface of the workpiece W. The magnet 84 and the target 87 form the sputtering electrode 80.

The cooling jacket 85 cools the target 87 by the cooling water supplied through the cooling water pipe 81.

The support plate 83 supports the magnet 84, the target 87, and the cooling jacket 85.

Inside the cooling water pipe 81, a cooling water passage 82 along the extending direction of the cooling water pipe 81 is formed. Although not illustrated in FIG. 9, the cooling water passage 82 includes: a water passage for supplying cooling water for cooling from the outside of the chamber 10 to the cooling jacket 85; and a water passage for discharging the cooling water used for cooling from the cooling jacket 85 to the outside of the chamber 10. In this manner, the cooling water pipe 81 circulates the cooling water through the outside of the chamber 10 and the cooling jacket 85 disposed in the chamber 10. An end of the cooling water pipe 81 on the inner side of the chamber 10 is connected to the cooling jacket 85. Inside the cooling jacket 85, a flow path of cooling water is formed and the cooling water flows. The cooling water is supplied from a cooling apparatus (not illustrated).

There is provided an earth shield 88 attached to a lower portion of the support plate 83. The earth shield 88 is attached with a gap of approximately 2 mm from the target 87.

There is provided an insulating material 86 disposed between the support plate 83 and the magnet 84. The insulating material 86 is also disposed on an outer peripheral portion of the magnet 84 in plan view. That is, the magnet 84 is retained by the support plate 83 via the insulating material 86.

The sputtering apparatus 70 performs an operation referred to as sputtering to form a thin film on the surface of the workpiece W. When the sputtering apparatus 70 performs sputtering, the pressure inside the chamber 10 is reduced by the pump unit 140 (refer to FIG. 1), and then an inert gas (Ar or the like) for sputtering is caused to flow into the chamber 10 from a gas supply pipe (not illustrated). Subsequently, the ionization of the gas flowing into the chamber 10 is promoted by the magnetic field generated by the magnet 84 of the sputtering apparatus 70, and generated ions are brought into a collision with the target 87. This ejects atoms of the target 87 from the surface of the target 87.

In a case where aluminum is used for the target 87, for example, the target 87 ejects atoms of aluminum when ions of the sputtering inert gas ionized in the vicinity of the target 87 collide with the target 87. The atoms of aluminum ejected from the target 87 are directed toward the negative side on the Z-axis. The workpiece W is located at a position facing the surface of the target 87 in the chamber 10, that is, on the negative side on the Z-axis. Therefore, the atoms of aluminum ejected from the target 87 move toward the workpiece W to adhere to the workpiece W, so as to be deposited on the surface of the workpiece W. This forms a thin film corresponding to the substance forming the target 87 on the surface of the workpiece W.

When the sputtering apparatus 70 is operating, the barrel 100 illustrated in FIG. 7 rotates, and thus, the workpiece W housed in the barrel 100 is stirred to perform uniform surface treatment on the workpiece W.

As described above, the surface treatment apparatus 1 of the first embodiment includes: treatment electrodes such as the plasma electrode 50 and the sputtering electrode 80; the barrel 100 (housing unit) that is installed at a position facing the treatment electrodes and is rotatable around the rotation shaft 113 having an inclination with respect to a horizontal direction, in a state where the workpiece W housed in the barrel 100; the chamber 10 housing the treatment electrodes and the barrel 100; the surface treatment device such as the plasma treatment apparatus 40 and the sputtering apparatus 70 including the treatment electrodes and configured to perform surface treatment on the workpiece W housed in the barrel 100; and the servo motor 120 (rotation device) that rotates the barrel 100 around the rotation shaft 113 when the surface treatment device performs surface treatment on the workpiece W. Accordingly, even when the workpiece W to be subjected to the surface treatment has a small three-dimensional shape, the surface treatment can be uniformly performed on the entire surface. In addition, since the workpiece W is stirred, the treatment time for performing the surface treatment can be reduced.

In the surface treatment apparatus 1 of the first embodiment, the barrel 100 (housing unit) includes at least either one of one or more protrusions 104, or one or more screws 106, on the side wall 101. Accordingly, when the barrel 100 rotates, the stored workpiece W can be evenly stirred.

Additionally, regarding the surface treatment apparatus 1 of the first embodiment, the size, shape, or number of the protrusions 104, or the size or spiral pitch of the screw 106 is variable according to the shape or size of the workpiece W. This makes it possible to perform efficient stirring appropriate for the workpiece W.

In addition, in the surface treatment apparatus 1 of the first embodiment, the barrel 100 (housing unit) is formed with a material having a permeability for the gas generated by operation of surface treatment device such as the plasma treatment apparatus 40 and the sputtering apparatus 70, and further includes the pump unit 140 (exhaust device) that sucks the gas flowing in from the upper portion of the barrel 100 from immediately below the barrel 100. This increases the exhaust efficiency, making it possible to reduce the treatment time for performing the surface treatment.

In the surface treatment apparatus 1 of the first embodiment, the servo motor 120 (rotation device) is capable of changing the rotation pattern of the barrel 100 (housing unit). This makes it possible to perform efficient stirring appropriate for the amount of the workpiece W.

In the surface treatment apparatus 1 of the first embodiment, the inclination of the rotation shaft 113 is changeable. This makes it possible to perform efficient stirring appropriate for the amount of the workpiece W, or the like.

In addition, the surface treatment apparatus 1 of the first embodiment includes the plasma treatment apparatus 40 that performs plasma treatment on the workpiece W or the sputtering apparatus 70 that performs sputtering on the workpiece W. This makes it possible to perform various types of surface treatment appropriate for the workpiece W.

In addition, the surface treatment apparatus 1 of the first embodiment continuously performs different surface treatments, for example, plasma treatment and sputtering, while keeping the workpiece W housed in the barrel 100 (housing unit). This makes it possible to perform various types of surface treatment appropriate for the workpiece W.

### Modification of First Embodiment

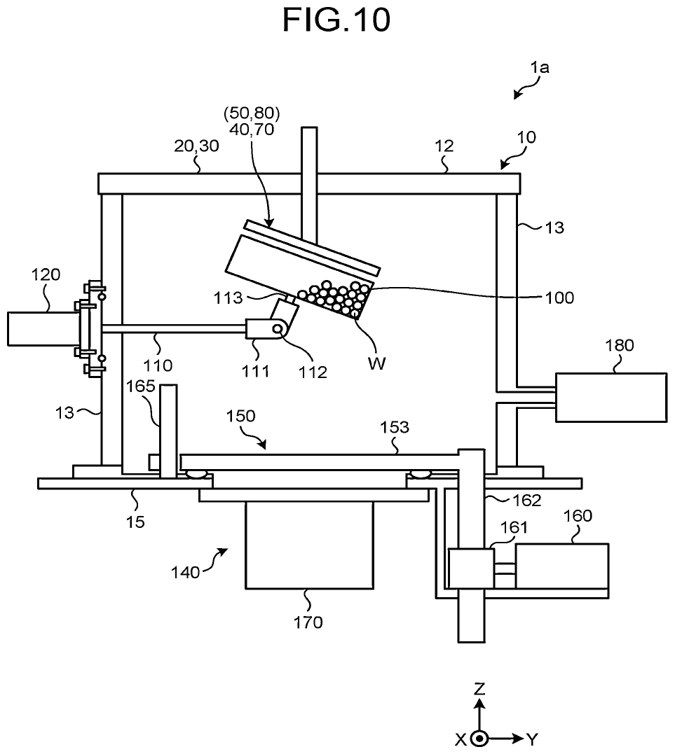

A surface treatment apparatus 1a according to a modification of the first embodiment will be described with reference to FIG. 10. FIG. 10 is a schematic diagram illustrating a schematic configuration of a surface treatment apparatus according to a modification of the first embodiment.

In the surface treatment apparatus 1a illustrated in FIG. 10, the plasma electrode 50 of the plasma treatment apparatus 40 or the sputtering electrode 80 of the sputtering apparatus 70 is disposed so as to be orthogonal to a rotation shaft 113. Since the inclination of the rotation shaft 113 is appropriately changed, the inclination of the plasma electrode 50 and the sputtering electrode 80 is also changeable according to the inclination of the rotation shaft 113.

In this manner, by locating the plasma electrode 50 or the sputtering electrode 80 so as to be orthogonal to the rotation shaft 113, the distance between the treatment electrode and the workpiece W can be reduced, making it possible to perform the surface treatment with higher efficiency.

### Second Embodiment

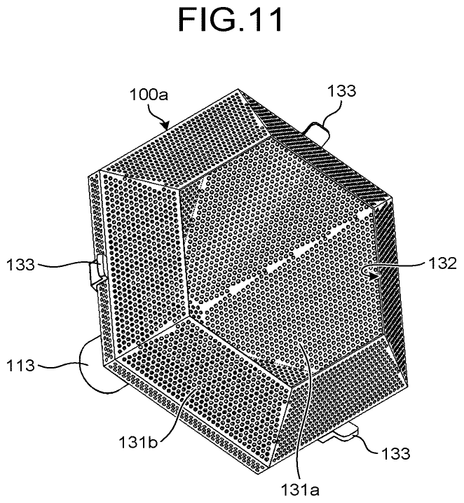

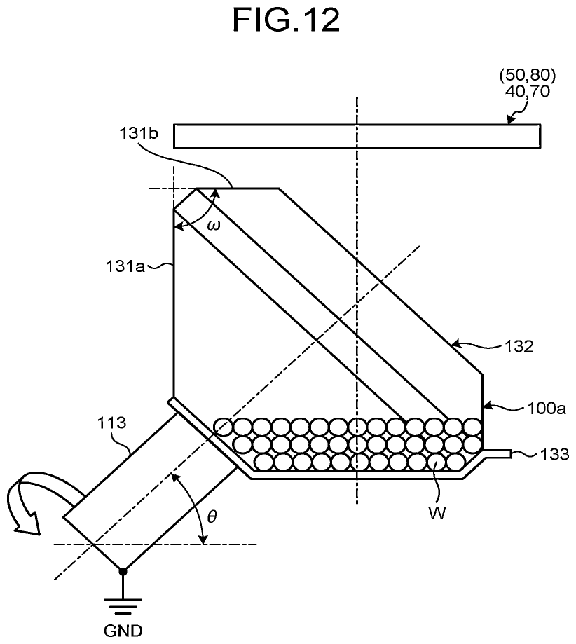

A surface treatment apparatus according to a second embodiment will be described with reference to FIGS. 11 and 12. FIG. 11 is an external perspective view illustrating an example of a schematic configuration of a barrel used in a surface treatment apparatus according to a second embodiment. FIG. 12 is side view illustrating an example of a schematic configuration of a barrel used in a surface treatment apparatus according to the second embodiment.

The surface treatment apparatus of the second embodiment includes a barrel 100a illustrated in FIG. 11. The barrel 100a has a housing portion for the workpiece W in the form of combining flat surfaces. The cross section of the barrel 100a in the direction orthogonal to the rotation shaft 113 has a polygonal shape. Regarding the barrel 100a illustrated in FIG. 11, a cross section in the direction orthogonal to the rotation shaft 113 has a hexagonal shape. The barrel 100a is an example of a housing unit in the present disclosure.

The outer peripheral edge of the barrel 100a includes: a lower side surface 131a closer to the rotation shaft 113; and an upper side surface 131b far from the rotation shaft 113. The lower side surface 131a and the upper side surface 131b are formed with a material having a plurality of small holes on the surface, such as perforated metal. In addition, there is provided an opening 132 formed at an upper end of the barrel 100a, that is, at an upper edge of the upper side surface 131b.

The barrel 100a is detachably connected to the rotation shaft 113 by three barrel supports 133. By releasing the connection by the barrel support 133, the barrel 100a is detached from the rotation shaft 113, and the workpiece W is put into or out from the opening 132.

In this manner, since the cross section of the barrel 100a in the direction orthogonal to the rotation shaft 113 has a polygonal shape, the workpiece W housed in the barrel 100a collides with the adjacent side surface and is stirred when the barrel 100a rotates around the rotation shaft 113. Therefore, the workpiece W can be sufficiently stirred without the presence of the protrusion 104 and the screw 106 described in the first embodiment.

As illustrated in FIG. 12, an angle ω formed by the lower side surface 131a and the upper side surface 131b is set to about 90°. The angle θ of the rotation shaft 113 is set such that the lower side surface 131a becomes substantially parallel to the treatment electrode (the plasma electrode 50 in plasma treatment apparatus 40 or the sputtering electrode 80 in sputtering apparatus 70) when the barrel 100a rotates around the rotation shaft 113.

By setting the orientation of the lower side surface 131a and the orientation of the upper side surface 131b in this manner, when the barrel 100a is rotated around the rotation shaft 113, the lower side surface 131a and the treatment electrode comes in a state where they are substantially parallel. Therefore, the workpiece W is housed in the lower side surface 131a at an equal height, and plasma or the like is uniformly applied on the workpiece W from the treatment electrode. This makes it possible to perform uniform surface treatment on the workpiece W.

In addition, since the lower side surface 131a and the upper side surface 131b makes an angle of about 90°, the upper side surface 131b comes in a state where it is substantially perpendicular to the treatment electrode when the barrel 100a is rotated around the rotation shaft 113. Therefore, when the barrel 100a rotates around the rotation shaft 113, it is possible to prevent the workpiece W from spilling out of the opening 132.

As described above, in the surface treatment apparatus of the second embodiment, the cross section of the barrel 100a (housing unit) in the direction orthogonal to the rotation shaft 113 has a polygonal shape. Therefore, the workpiece W can be sufficiently stirred without the presence of the protrusion 104 or the screw 106.

In addition, in the surface treatment apparatus of the second embodiment, a part of the plane (lower side surface 131a) forming the barrel 100a (housing unit) comes in a state where it is substantially parallel to the treatment electrode when the barrel 100a is rotated around the rotation shaft 113. This makes it possible to perform uniform surface treatment on the workpiece W.

In addition, in the surface treatment apparatus of the second embodiment, a part of the plane (upper side surface 131b) forming the barrel 100a (housing unit) comes in a state where it is substantially perpendicular to the treatment electrode when the barrel 100a is rotated around the rotation shaft 113. This makes it possible to prevent the workpiece W from spilling out of the opening 132.

The embodiments of the present invention have been described as above. The above-described embodiments have been presented as examples, and are not intended to limit the scope of the present invention. This novel embodiment can be implemented in various other forms. In addition, various omissions, substitutions, and alteration can be made without departing from the scope and spirit of the invention. In addition, the embodiments are included in the scope and spirit of the invention, and is included in the invention described in the claims and the equivalent scope thereof.

### EXPLANATIONS OF LETTERS OR NUMERALS

1, 1a SURFACE TREATMENT APPARATUS
10 CHAMBER
11 OPENING
12 UPPER WALL
13 SIDE WALL
15 BOTTOM
18a, 18b, 19 ATTACHMENT STRUCTURE
20 FIRST OPEN/CLOSE MEMBER
21, 31 HINGE
30 SECOND OPEN/CLOSE MEMBER
40 PLASMA TREATMENT APPARATUS (SURFACE TREATMENT DEVICE)
50 PLASMA ELECTRODE (TREATMENT ELECTRODE)
57 GAS SUPPLY HOLE
59 SUPPORT MEMBER
60, 62 PLATE-SHAPED CONDUCTOR
61 VOID
63 SPACER
64 GAS INTRODUCTION PORTION
66 GAS SUPPLY PIPE
67 RECESS
68, 69 THROUGH HOLE
70 SPUTTERING APPARATUS (SURFACE TREATMENT DEVICE)
73 MATCHING BOX (MB)
74 RADIO FREQUENCY POWER SOURCE (RF)
75 EARTH
76 MASS FLOW CONTROLLER (MFC)
77 SUPPORT PLATE
78 GAS SUPPLY PORTION
79 RETAINING MEMBER
80 SPUTTERING ELECTRODE (TREATMENT ELECTRODE)
81 COOLING WATER PIPE
82 COOLING WATER PASSAGE
83 SUPPORT PLATE
84 MAGNET
85 COOLING JACKET
86 INSULATING MATERIAL
87 TARGET
88 EARTH SHIELD
100, 100a BARREL (HOUSING UNIT)
101 SIDE WALL
102 BOTTOM SURFACE
104 PROTRUSION
106 SCREW
106a, 106b END
107 SIDE WALL
108 BOTTOM SURFACE
109 ATTACHMENT PORTION
110, 113 ROTATION SHAFT
111 UNIVERSAL JOINT
112 ROTATION SHAFT FULCRUM
120 SERVO MOTOR (ROTATION DEVICE)
131a LOWER SIDE SURFACE
131b UPPER SIDE SURFACE
132 OPENING
133 BARREL SUPPORT
140 PUMP UNIT (EXHAUST DEVICE)
150 FLOW RATE REGULATING VALVE
153 ELEVATING VALVE
160 SERVO ACTUATOR
161 WORM JACK
162 ELEVATING SHAFT
165 VALVE GUIDE
170 TURBOMOLECULAR PUMP
180 VACUUM GAUGE
S GROOVE
W WORKPIECE
θ, ω ANGLE

1. A surface treatment apparatus comprising:
a treatment electrode;
a housing unit that is installed at a position facing the treatment electrode and is rotatable around a rotation shaft having an inclination with respect to a horizontal direction while housing a workpiece;
a chamber that houses the treatment electrode and the housing unit;
a surface treatment device that performs surface treatment on the workpiece housed in the housing unit, and includes the treatment electrode; and
a rotation device that rotates the housing unit around the rotation shaft when the surface treatment device performs the surface treatment on the workpiece.

2. The surface treatment apparatus according to claim 1,
wherein the housing unit includes at least either of one or more protrusions, or one or more screws, on a side wall.

3. The surface treatment apparatus according to claim 2,
wherein a size, a shape, or a number of the protrusions, or a size or a spiral pitch of the screws is variable according to a shape or a size of the workpiece.

4. The surface treatment apparatus according to claim 1,
wherein the inclination of the rotation shaft is changeable.

5. The surface treatment apparatus according to claim 1,
wherein the treatment electrode is disposed orthogonal to the rotation shaft.

6. The surface treatment apparatus according to claim 1,
wherein a cross section of the housing unit in a direction orthogonal to the rotation shaft is formed into a polygonal shape.

7. The surface treatment apparatus according to claim 6,
wherein a partial plane forming the housing unit comes in a state where it is substantially parallel to the treatment electrode when the housing unit is rotated around the rotation shaft.

8. The surface treatment apparatus according to claim 6,
wherein a partial plane forming the housing unit comes in a state where it is substantially perpendicular to the treatment electrode when the housing unit is rotated around the rotation shaft.

9. The surface treatment apparatus according to claim 1, wherein
the housing unit includes a material that has a permeability for a gas generated by an operation of the surface treatment device, and
the surface treatment apparatus further comprises an exhaust device that sucks a gas flowing from an upper portion of the housing unit, from immediately below the housing unit.

10. The surface treatment apparatus according to claim 1,
wherein the rotation device is capable of changing a rotation pattern of the housing unit.

11. The surface treatment apparatus according to claim 2,
wherein the surface treatment device includes a plasma treatment apparatus that performs plasma treatment on the workpiece or a sputtering apparatus that performs sputtering on the workpiece.

12. The surface treatment apparatus according to claim 11,
wherein different surface treatments are continuously performed while keeping the workpiece housed in the housing unit.

13. The surface treatment apparatus according to claim 6,
wherein the surface treatment device includes a plasma treatment apparatus that performs plasma treatment on the workpiece or a sputtering apparatus that performs sputtering on the workpiece.
